(19) United States
(12) Patent Application Publication
(10) Pub. No.: US 2014/0043016 A1
(43) Pub. Date: Feb. 13, 2014

(54) SYSTEM INCLUDING A MAGNETOELECTRIC DEVICE FOR POWERING A LOAD OR VISUALLY INDICATING AN ENERGIZED POWER BUS

(71) Applicants: JOHN A. KOVACICH, Waukesha, WI (US); SARIN KUMAR ANAKKAT KOYILOTHU, Bangalore (IN)

(72) Inventors: JOHN A. KOVACICH, Waukesha, WI (US); SARIN KUMAR ANAKKAT KOYILOTHU, Bangalore (IN)

(21) Appl. No.: 13/584,188

(22) Filed: Aug. 13, 2012

(51) Int. Cl. G01R 19/15; H01F 38/14

(52) U.S. Cl. 324/133; 307/104

(57) ABSTRACT

A system includes a power bus, a capacitive divider and a magnetoelectric device. The capacitive divider includes a first capacitance element electrically connected in series with a second capacitance element. The first capacitance element is electrically interconnected with the power bus. The second capacitance element is electrically connected between the first capacitance element and ground. The capacitive divider causes a current to flow between the power bus and the ground when the power bus is energized. The current generates a magnetic field. The magnetoelectric device includes an input inputting the magnetic field and an output outputting a voltage. An indicator or a load is driven by the voltage of the output of the magnetoelectric device.

### BACKGROUND

1. Field

The disclosed concept pertains generally to power bus apparatus and, more particularly, to power systems including an alternating current power bus. The disclosed concept also pertains to indicator systems for an alternating current power bus.

2. Background Information

Inside of electrical control centers, as well as other electrical environments, there are bus bar wiring conductors and lugged cable connection conductors, as well as conductor taps for three-phase power. This is true regardless whether the corresponding electrical product is for low-voltage or for medium-voltage.

Maintenance personnel can be harmed when accidentally touching energized surfaces of power bus bars.

Electrical sensors of various types are used to detect the current flowing through a conductor. Such sensors include, for example, a single Hall effect sensor that produces an output voltage indicative of the current magnitude as well as more conventional current sensors such as a shunt resistor or a current transformer.

Hall effect devices have been used to sense variations in magnetic flux resulting from a flow of current through a conductor. Some of these known devices have used a flux concentrator to concentrate magnetic flux emanating from the flow of current through the conductor. It has previously been suggested that electrical current sensing apparatus could be constructed in the manner disclosed in U.S. Pat. Nos. 4,587,509; and 4,616,207.

It is also known to measure the current in a conductor with one or two appropriately placed Hall sensors that measure flux density near the conductor and to convert the same to a signal proportional to current. See, for example, U.S. Pat. Nos. 6,130,599; 6,271,656; 6,642,704; and 6,731,105.

U.S. Pat. No. 7,145,322 discloses a power bus current sensor, which is powered by a self-powered inductive coupling circuit. A sensor senses current of the power bus. A power supply employs voltage produced by magnetically coupling the power bus to one or more coils, in order to power the sensor and other circuitry from flux arising from current flowing in the power bus.

U.S. Patent Application Pub. No. 2007/0007968 discloses a system for monitoring an electrical power system including one or more transducer units, each of which has a current measuring device and a voltage measuring device coupled to a respective one of the phase conductors of the power system, and a transducer wireless communications device. The transducer unit includes a battery for providing power to the components thereof. The battery is connected to a trickle charger, which, in turn, is electrically coupled to a phase conductor. The trickle charger is a known parasitic power charger that draws power from the phase conductor and uses it to charge the battery.

A known prior proposal for monitoring a bus bar wiring conductor employs a current transformer to harvest energy or an associated signal, through coupling to the magnetic field caused by current flowing through the conductor. However, if a load is not connected to the conductor, and, thus, no current is flowing, then a current transformer (or magnetic coupling) will not function.

The magnetoelectric effect (ME) is the appearance of an electric polarization P upon applying a magnetic field H (i.e., the direct ME effect, ME_{H}), wherein P=αH and α is a constant, or the appearance of a magnetization M upon applying an electric field E (i.e., the converse ME effect, ME_{E}), wherein M=αE.

In other words:

$${ME}_{H} effect = \frac{magnetic}{mechanical} \times \frac{mechanical}{electric}$$

$${ME}_{E} effect = \frac{electric}{mechanical} \times \frac{mechanical}{magnetic}$$

The mechanical aspect of the ME effect is a kind of hidden intrinsic aspect. The real output is the electric field when the input is a magnetic field, or the magnetic field when the input is an electric field. When an electric field is applied, a piezoelectric component of the ME material is excited and is mechanically deformed. This mechanical deformation is passed on to a magneto-strictive component of the ME material, which is excited to give a magnetic field output. Conversely, when a magnetic field is applied, this excites the magneto-strictive component of the ME material and generates a mechanical deformation. This mechanical deformation induces an electric field in the piezoelectric component of ME material.

The intrinsic magnetoelectric effect is a property that originates from the coupling of electric and magnetic subsystems in single-phase magnetoelectric multiferroic materials. The ME coefficient is relatively very small and exhibits the ME property at relatively low temperatures; hence, this is not suitable for many applications. BiFeO₃ is the only known room temperature ME material.

The extrinsic magnetoelectric effect is a property shown by composite materials that have different individual properties. There is elastic coupling between a piezoelectric phase and a piezomagnetic phase. The magnetoelectric coefficients are one or two orders of magnitude higher than that of the present-day single-phase material. Suitable materials include PZT/NiFe₂O₄, Terfenol-D/PZT, Terfenol-D/PZT/Terfenol-D trilayer, and Metglas/polyvinylidene difluoride (PVDF).

ME composites are made out of individual materials which have been studied well and whose properties are known (e.g., without limitation, PZT; ferrite materials; Terfenol).

There is room for improvement in indicator systems for a power bus.

There is also room for improvement in systems powered by a power bus.

### SUMMARY

These needs and others are met by embodiments of the disclosed concept in which a capacitive divider provides a current from an energized power bus. This current generates a magnetic field, which is sensed by a magnetoelectric effect (ME) device and is converted to a voltage, in order to drive a load or an indicator.

Other embodiments of the disclosed concept are for an energized power bus having a current flowing therethrough. This current generates a magnetic field, which is sensed by a ME device and converted to a voltage, in order to drive a load or an indicator.

In accordance with one aspect of the disclosed concept, a system comprises: a power bus; a capacitive divider comprising a first capacitance element electrically connected in series with a second capacitance element, the first capacitance element being electrically interconnected with the power bus, the second capacitance element being electrically connected between the first capacitance element and ground, the capacitive divider causing a current to flow between the power bus and the ground when the power bus is energized, the current generating a magnetic field; a magnetoelectric device comprising an input inputting the magnetic field and an output outputting a voltage; and an indicator or a load driven by the voltage of the output of the magnetoelectric device.

The power bus may have no current flowing therethrough, or may have current flowing therethrough.

The first capacitance element may be formed by a capacitor. The second capacitance element may be formed by an antenna providing the second capacitance element electrically connected to the ground. The magnetoelectric device may be positioned proximate the capacitor to input the magnetic field generated by the current flowing between the power bus and the ground.

As another aspect of the disclosed concept, a system comprises: a power bus having a current flowing therethrough, the current generating a magnetic field; a magnetoelectric device comprising an input inputting the magnetic field and an output outputting a voltage; and an indicator or a load driven by the voltage of the output of the magnetoelectric device.

### BRIEF DESCRIPTION OF THE DRAWINGS

A full understanding of the disclosed concept can be gained from the following description of the preferred embodiments when read in conjunction with the accompanying drawings in which:

FIGS. 1 and 2 are block diagrams of systems including a magnetoelectric device for powering a load or visually indicating an energized power bus in accordance with embodiments of the disclosed concept.

### DESCRIPTION OF THE PREFERRED EMBODIMENTS

As employed herein, the term “number” shall mean one or an integer greater than one (i.e., a plurality).

As employed herein the term “switchgear device” shall expressly include, but not be limited by, a circuit interrupter, such as a circuit breaker (e.g., without limitation, low-voltage or medium-voltage or high-voltage); a motor controller/starter; a busway; and/or any suitable device which carries or transfers current from one place to another.

As employed herein the term “power bus” shall mean a power conductor; a power bus bar; a power line; a power phase conductor; a power cable; and/or a power bus structure for a power source, a circuit interrupter or other switchgear device, or a load powered from the power bus.

The disclosed concept can provide a safety feature for electrical control enclosures (e.g., without limitation, motor control centers) by visually indicating (e.g., without limitation, using a high-contrast indicator) to a maintenance worker, electrician, technician or other electrical personnel that a particular power bus has been energized by an applied voltage even though an electrical current may not be flowing therethrough or that a load may not be electrically connected thereto.

The disclosed concept can also provide energy harvesting for remote wireless sensor networks, remote sensing elements and/or other suitable remote circuits associated with electrical control enclosures and associated busway and cable wiring runs by generating useable energy from a particular power bus that has been energized by an applied voltage even though an electrical current may not be flowing therethrough or that a load may not be electrically connected thereto.

The disclosed concept employs a magnetic field that is generated by current flowing either in a capacitive divider electrically interconnected with an energized power bus, or in the energized power bus. A magnetoelectric device generates an electric field from the magnetic field. The voltage of the generated electric field is employed to “turn-on” a device or material that is susceptible to the generated electric field, for example, a “load” (e.g., without limitation, a capacitive or resistive load that might be associated with a wireless sensor network) or an “indicator” (e.g., without limitation, a safety indicator to indicate an energized power bus).

The disclosed concept provides an electrically passive system and does not employ batteries or active electronics.

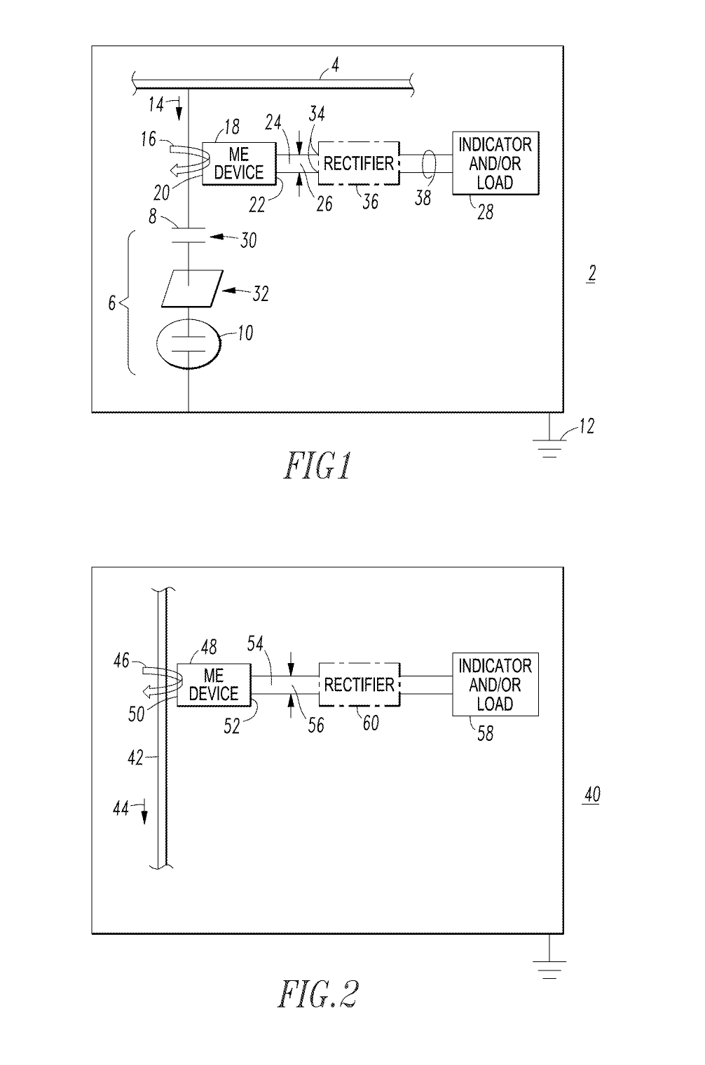

Referring to FIG. 1, a system 2 includes a power bus 4, a capacitive divider 6 having a first capacitance element 8 electrically connected in series with a second capacitance element 10. The first capacitance element 8 is electrically interconnected with the power bus 4. The second capacitance element 10 is electrically connected between the first capacitance element 8 and ground 12. The capacitive divider 6 causes a current 14 to flow between the power bus 4 and the ground 12 when the power bus 4 is energized. The current 14 generates a magnetic field 16. A magnetoelectric (ME) device 18 includes an input 20 inputting the magnetic field 16 and an output 22 outputting an electric field 24 having a voltage 26. An indicator or a load 28 is driven by the voltage 26 of the output 22 of the ME device 18.

### Example 1

The power bus 4 may have no current flowing therethrough, or may have current flowing therethrough.

### Example 2

The first capacitance element 8 may be formed by a capacitor 30. The second capacitance element 10 may be formed by an antenna 32 providing the second capacitance element 10 electrically connected to the ground 12. The ME device 18 may be positioned proximate the capacitor 30 to input the magnetic field 16 generated by the current 14 flowing between the power bus 4 and the ground 12.

As shown in FIG. 1, the ME device 18 is positioned proximate the first capacitance element 8 and senses the local magnetic field 16 generated by the current 14 flowing in the capacitive (voltage) divider 6. The first capacitance element 8 can be provided by the conventional capacitor 30 that is electrically connected between the power bus 4 and the antenna 32, in order to allow the capacitive divider 6 to generate the relatively small current 14 in the capacitor 30 to create the relatively small magnetic field 16 that is employed by the ME device 18. The electrical output 22 of the ME device 18 is electrically coupled to the input 34 of an optional rectifier 36 (shown in phantom line drawing), the output 38 of which energizes the indicator or the load 28 with a resulting DC voltage. The antenna 32 provides a suitable parasitic capacitive coupling to the ground 12.

For example, the example antenna 32 is employed in order that no hard wiring is electrically connected between the energized power bus 4 and the ground 12. For example, users of switchgear (not shown) do not want to have a jumper wire (not shown) strung inside a switchgear cabinet (not shown), as that would represent a hazard. The example antenna 32 could take any suitable shape with a wide range of alternative structures (e.g., without limitation, a square plate; a rectangular plate; a round plate; an elongated wire; a whip antenna; a telescoping antenna; a sphere; a solid shape; any suitable antenna that can capacitively couple a node to electrical ground).

The resulting capacitive divider 6, as formed by the capacitor 30 and the antenna 32, conducts the current 14, which generates the magnetic field 16 arising from the current 14 flowing in the capacitive divider 6. The magnetic field 16 is sensed by the ME device 18 to drive the indicator or the load 28. The capacitive divider 6 permits the current 14 to flow through the series combination of the capacitor 30 and the antenna 32. The current 14 generates the magnetic field 16 that interacts with the ME device 18.

Referring to FIG. 2, a system 40 includes a power bus 42 having a current 44 flowing therethrough. The current 44 generates a magnetic field 46. A ME device 48 includes an input 50 inputting the magnetic field 46 and an output 52 outputting an electric field 54 having a voltage 56. An indicator or a load 58 is driven by the voltage 56 of the output 52 of the ME device 48.

### Example 3

In FIGS. 1 and 2, the power bus 4,42 can be an energized bus bar or conductor.

### Example 4

The indicator or the load 28,58 can be an indicator which indicates that the respective power bus 4,42 is energized.

### Example 5

The indicator or the load 28,58 can be a load which is powered when the respective power bus 4,42 is energized.

### Example 6

The indicator or the load 28,58 can be directly driven by the voltage 26,56 of the output 22,52 of the ME device 18,48, respectively. In that event, the optional rectifier 36 or 60 (shown in phantom line drawing) is not employed.

### Example 7

The voltage 26,56 of the output 22,52 of the ME device 18,48 can be an alternating current (AC) voltage. The optional rectifier 36,60 (shown in phantom line drawing) can be electrically connected between the output 22,52 of the ME device 18,48 and the indicator or the load 28,58, respectively, in order to provide a direct current (DC) voltage thereto.

### Example 8

The indicator or the load 28,58 can be a capacitive load or a resistive load.

### Example 9

The indicator or the load 28,58 can be a safety indicator to indicate that the respective power bus 4,42 is energized.

### Example 10

The indicator or the load 28,58 can be a non-lighted, visual indication of the respective power bus 4,42 being energized.

### Example 11

The ME device 18,48, such as a magnetoelectric composite element, can be held in a suitable structure (not shown) that allows for the magnetic field 16,46 of a current-carrying conductor (e.g., without limitation, capacitive divider 6; power bus 42) to interact in a suitable manner that actuates the magnetoelectric composite element in combination with the indicator 28,58, in order to provide a non-lighted, suitably high-contrast visual indication of power bus “turn-on” status.

For example, in FIG. 1, the magnetoelectric composite element is placed proximate the capacitor 30 of the capacitive divider 6 with capacitive coupling to the ground 12 (e.g., a low potential). The resulting low current 14 generated for the magnetoelectric section by the capacitive divider 6 would, thus, engage the magnetoelectric composite element, and through its self-magnetic-field-sensing mechanism, would provide a relatively high voltage per oersted (Oe) (e.g., a centimeter-gram-second unit of magnetic intensity, equal to a magnetic pole of unit strength when undergoing a force of one dyne in a vacuum) sensitivity in order to allow for a useable energy and/or voltage. The voltage 26 generated within the magnetoelectric composite element can be converted from AC to DC through the use of the optional rectifier 36. In combination with this rectified voltage, an equivalent circuit characteristic, such as a capacitor (not shown) of the indicator 28, can be charged through the use of the rectified voltage for use in powering a device such as the indicator 28. For example, the indicator 28 can have equivalent circuit characteristics of a capacitor, that is charged through the use of the rectified voltage.

### Example 12

The main advantages of ME devices, such as 18 or 48, include providing a passive system in which no battery is needed to operate a sensing element. Also, a relatively high output voltage is provided as compared to known Hall and anisotropic magneto-resistive (AMR) types of sensors. For example, the ME output 22,52 is 75 mV/Oe for ferrite/PZT, and 234 mV/Oe for Terfenol-D/PZT. The relatively high voltage output 52,22 provides for a good response even at the relatively small magnetic field 46,16 associated with the relatively low current 44,14 passing through the power bus 42 or other current carrying conductor, such as the capacitive divider 6, respectively.

### Example 13

The system 2 of FIG. 1 is operational even if no current is flowing in the energized power bus 4. Here, a current carrying conductor is formed by the capacitive divider 6. When the current 14 or 44 flows in either the capacitive divider 6 (FIG. 1) or the energized power bus 42 (FIG. 2), then there is the corresponding magnetic field 16 or 46 that is generated as a result of that current. In either event, the magnetic field 16 or 46 is sensed by the ME device 18 or 48 and the voltage 26 or 56 is output to the indicator or the load 28 or 58, respectively.

### Example 14

The system 40 of FIG. 2 is for the current 44 flowing in the energized power bus 42, which is able to provide the magnetic field 46 directly with no need for the capacitive divider 6 of FIG. 1. A drawback, however, is that this technology then competes with current transformers (not shown), which are relatively inexpensive, but which cannot work if no current flows in the energized power bus 42.

### Example 15

Non-limiting examples of the ME device 18,48 can be two different types: (1) an intrinsic element, where a single phase material shows the ME effect (e.g., without limitation, BiFeO₃, which is the only known room temperature ME material; Cr₂O₃, TbFeO₃; FeₓGa₂₋ₓO₃); and (2) an extrinsic element, where laminates can be made by sandwiching a piezoelectric material and a magnetoelectric material (e.g., without limitation, PZT/NiFe₂O₄; Terfenol-D/PZT; Terfenol-D/PZT/Terfenol-D trilayer; Metglas/polyvinylidene difluoride (PVDF)).

While specific embodiments of the disclosed concept have been described in detail, it will be appreciated by those skilled in the art that various modifications and alternatives to those details could be developed in light of the overall teachings of the disclosure. Accordingly, the particular arrangements disclosed are meant to be illustrative only and not limiting as to the scope of the disclosed concept which is to be given the full breadth of the claims appended and any and all equivalents thereof.

What is claimed is:

1. A system comprising:
a power bus;
a capacitive divider comprising a first capacitance element electrically connected in series with a second capacitance element, said first capacitance element being electrically interconnected with said power bus, said second capacitance element being electrically connected between said first capacitance element and ground, said capacitive divider causing a current to flow between said power bus and said ground when said power bus is energized, said current generating a magnetic field;
a magnetoelectric device comprising an input inputting said magnetic field and an output outputting a voltage; and
an indicator or a load driven by the voltage of the output of said magnetoelectric device.

2. The system of claim 1 wherein said power bus is an energized bus bar or conductor.

3. The system of claim 1 wherein said power bus has no current flowing therethrough.

4. The system of claim 1 wherein said power bus has current flowing therethrough.

5. The system of claim 1 wherein said first capacitance element is formed by a capacitor.

6. The system of claim 5 wherein said second capacitance element is formed by an antenna providing the second capacitance element electrically connected to said ground.

7. The system of claim 5 wherein said magnetoelectric device is positioned proximate said capacitor to input the magnetic field generated by the current flowing between said power bus and said ground.

8. The system of claim 1 wherein said indicator or said load is an indicator which indicates that said power bus is energized.

9. The system of claim 1 wherein said indicator or said load is a load which is powered when said power bus is energized.

10. The system of claim 1 wherein said indicator or said load is directly driven by the voltage of the output of said magnetoelectric device.

11. The system of claim 1 wherein the voltage of the output of said magnetoelectric device is an alternating current voltage; and wherein a rectifier is electrically connected between the output of said magnetoelectric device and said indicator or said load.

12. A system comprising:
a power bus having a current flowing therethrough, said current generating a magnetic field;
a magnetoelectric device comprising an input inputting said magnetic field and an output outputting a voltage; and
an indicator or a load driven by the voltage of the output of said magnetoelectric device.

13. The system of claim 12 wherein said power bus is an energized bus bar or conductor.

14. The system of claim 12 wherein said indicator or said load is an indicator which indicates that said power bus is energized.

15. The system of claim 12 wherein said indicator or said load is a load which is powered when said power bus is energized.

16. The system of claim 12 wherein said indicator or said load is directly driven by the voltage of the output of said magnetoelectric device.

17. The system of claim 12 wherein the voltage of the output of said magnetoelectric device is an alternating current voltage; and wherein a rectifier is electrically connected between the output of said magnetoelectric device and said indicator or said load.

18. The system of claim 12 wherein said load is a capacitive load or a resistive load.

19. The system of claim 12 wherein said indicator is a safety indicator to indicate that said power bus is energized.

20. The system of claim 12 wherein said indicator is a non-lighted, visual indication of said power bus being energized.

21. The system of claim 12 wherein the magnetoelectric device is selected from the group consisting of an intrinsic element and an extrinsic element.
